(19) United States
(12) Patent Application Publication
(10) Pub. No.: US 2021/0318475 A1
(43) Pub. Date: Oct. 14, 2021

(54) ANGULAR FILTER AND METHOD FOR MANUFACTURING SAME

(71) Applicant: ISORG, Limoges CEDEX 3 (FR)

(72) Inventors: Agathe PUSZKA, GRENOBLE (FR); Wilfrid SCHWARTZ, GRENOBLE (FR); Tindara VERDUCI, GRENOBLE (FR); Benjamin BOUTHINON, GRENOBLE (FR)

(21) Appl. No.: 17/260,955

(22) PCT Filed: Jul. 18, 2019
(86) PCT No.: PCT/EP2019/069454

§ 371 Date: Jan. 15, 2021

(30) Foreign Application Priority Data
Jul. 19, 2018 (FR) 1856709

(51) Int. Cl. G02B 5/20; H01L 27/30; G03F 7/00

(52) U.S. Cl. CPC G02B 5/20; G02B 2207/123; G03F 7/0005; H01L 27/307

(57) ABSTRACT

A method of manufacturing an optical system including an angular filter having a stack of first and second elementary angular filters, the method including exposing a layer of positive resist through the first elementary angular filter and removing the exposed portions of the layer to form holes crossing the layer, the layer crossed by the holes forming the second elementary angular filter.

The present patent application claims the priority benefit of French patent application FR18/56709 which is herein incorporated by reference.

### TECHNICAL BACKGROUND

The present disclosure concerns angular filters and methods of manufacturing the same.

### PRIOR ART

An image acquisition system generally comprises an image sensor and an optical system, interposed between the sensitive portion of the image sensor and the object to be imaged and which enables to form a sharp image of the object to be imaged on the sensitive portion of the image sensor. The optical system may particularly comprise a plurality of levels of lenses.

However, in certain cases, it is not possible to have such an optical system between the sensitive portion of the image sensor and the object to be imaged. This is particularly true when the image sensor occupies a significant surface area, greater than one square centimeter, and the distance between the object to be imaged and the sensitive portion of the image sensor is smaller than one centimeter.

The object to be imaged would then have to be placed at closest to the image sensor so that the image which forms on the sensitive portion of the image sensor is sufficiently sharp. However, there may be a distance between the object and the image sensor, so that the sharpness of the image which forms on the sensitive portion of the image sensor may be insufficient for certain applications, for example, for the capture of fingerprints.

To increase the sharpness of the image acquired by the image sensor of an image acquisition system in the absence of a complex optical system, a possibility is to cover the image sensor with an optical system of simple structure comprising an angular filter, formed by an opaque film crossed by holes. However, for certain applications, to obtain a proper angular filtering, the aspect ratio of the filter openings, that is, the ratio of the thickness of the film to the lateral dimension of each opening, should be greater than 1.

It is difficult to obtain such aspect ratios with methods of direct shaping of colored materials, for example, colored resins, which may be used at an industrial scale.

### SUMMARY

An object of an embodiment is to totally or partly overcome at least part of the disadvantages of angular filters and of their previously-described manufacturing methods.

An object of an embodiment is a method of manufacturing an angular filter comprising openings enabling to obtain a ratio of the depth of the openings to the lateral dimension of each opening which is greater than 1.

Another object of an embodiment is to be able to implement the angular filter manufacturing method at an industrial scale.

For this purpose, an embodiment provides a method of manufacturing an optical system comprising an angular filter comprising a stack of first and second elementary angular filters, the method comprising exposing a layer of positive resist through the first elementary angular filter and removing the exposed portions of the layer to form holes crossing said layer, said layer crossed by said holes forming the second elementary angular filter.

According to an embodiment, the optical system comprises a surface intended to receive a first radiation, the layer being opaque to the first radiation, the angular filter being configured to block the rays of said first radiation having an incidence relative to a direction orthogonal to the surface greater than a threshold and to give way to rays of said first radiation having an incidence relative to a direction orthogonal to the surface smaller than the threshold.

According to an embodiment, the exposure step comprises exposing the layer to a second radiation through the first elementary angular filter, the positive resist being photosensitive to the second radiation.

According to an embodiment, the first radiation is in the visible range and/or in the infrared range.

According to an embodiment, each first and second elementary angular filter comprises a layer crossed by holes.

An embodiment also provides an optical system comprising an angular filter comprising a stack of first and second elementary angular filters, the second elementary angular filter comprising a layer of positive resist and holes crossing said layer.

According to an embodiment, the system comprises a surface intended to receive a first radiation, the layer is opaque to the first radiation, the angular filter being configured to block the rays of said first radiation having an incidence relative to a direction orthogonal to the surface greater than a threshold and to give way to rays of said first radiation having an incidence relative to a direction orthogonal to the first surface smaller than the threshold.

According to an embodiment, the positive resist is photosensitive to the second radiation.

According to an embodiment, the system comprises an additional layer interposed between the first elementary angular filter and the second elementary angular filter at least partially transparent to the first radiation.

According to an embodiment, for each hole, the ratio of the sum of the thicknesses of the first elementary angular filter, of the additional layer, and of the second elementary angular filter, measured perpendicularly to the surface, to the width of the hole, measured parallel to the surface, is greater than 1, preferably varies from 1 to 10.

According to an embodiment, the holes are arranged in rows and in columns, the pitch between adjacent holes of a same row or of a same column varying from 1 μm to 100 μm.

According to an embodiment, the height of each hole, measured along a direction orthogonal to the surface, varies from 1 μm to 50 μm.

According to an embodiment, the width of each hole, measured parallel to the surface, varies from 1 μm to 100 μm.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified cross-section view illustrating an embodiment of an image acquisition system comprising an angular filter;

FIG. 2 is a cross-section view of the angular filter shown in FIG. 1;

FIG. 3 is a partial simplified cross-section view of the structure obtained at a step of an embodiment of a method of manufacturing the angular filter shown in FIGS. 1 and 2;

FIG. 4 is a partial simplified cross-section view of the structure obtained at another step of an embodiment of a method of manufacturing the angular filter shown in FIGS. 1 and 2;

FIG. 5 is a partial simplified cross-section view of the structure obtained at another step of an embodiment of a method of manufacturing the angular filter shown in FIGS. 1 and 2;

FIG. 6 is a partial simplified cross-section view of the structure obtained at another step of an embodiment of a method of manufacturing the angular filter shown in FIGS. 1 and 2; and

FIG. 7 is a partial simplified cross-section view of the structure obtained at another step of an embodiment of a method of manufacturing the angular filter shown in FIGS. 1 and 2.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the structure of an image sensor is well known by those skilled in the art and is not described in detail hereafter.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., unless specified otherwise, it is referred to the orientation of the drawings or to an optical system in a normal position of use.

Unless specified otherwise, the expressions “around”, “approximately”, “substantially” and “in the order of” signify within 10%, and preferably within 5%.

In the following description, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%.

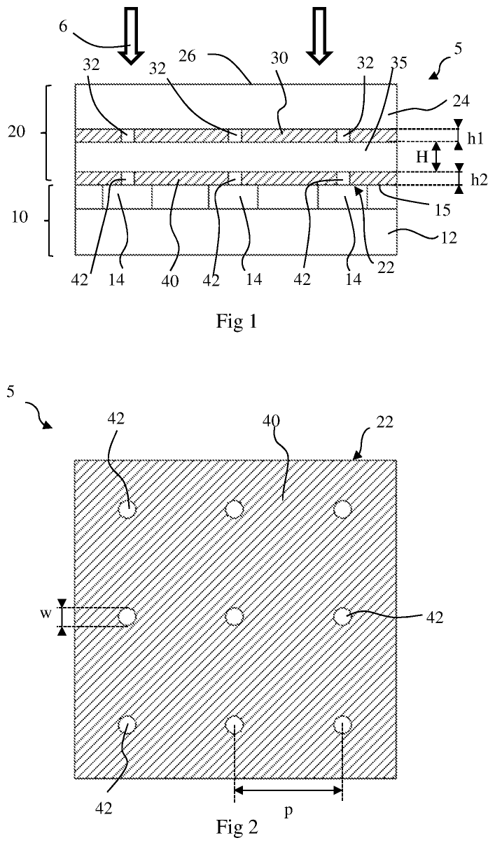

FIGS. 1 and 2 are partial simplified cross-section views along perpendicular cross-section planes of an embodiment of an image acquisition system 5 receiving a radiation 6. Image acquisition system 5 comprises, from bottom to top in FIG. 1:
an image sensor 10 having an upper surface 15; and
an optical system 20 covering surface 15.

Image sensor 10 comprises a support 12 and an array of photon sensors 14, also called photodetectors, arranged between support 12 and optical system 20. Photodetectors 14 may be covered with a transparent protection coating, not shown. Image sensor 10 further comprises conductive tracks and switching elements, particularly transistors, not shown, enabling to select photodetectors 14. Photodetectors 14 may be made of organic materials. Photodetectors 14 may correspond to organic photodiodes (OPD) or to organic photoresistors. The surface of image sensor 10 opposite optical system 20 and containing photodetectors 14 is greater than 1 cm², preferably greater than 5 cm², more preferably greater than 10 cm², in particular greater than 20 cm². The upper surface 15 of image sensor 10 may be substantially planar.

According to an embodiment, each photodetector 14 is capable of detecting an electromagnetic radiation in a wavelength range from 400 nm to 1,100 nm. All photodetectors 14 may be capable of detecting an electromagnetic radiation in the same wavelength range. As a variation, photodetectors 14 may be capable of detecting an electromagnetic radiation in different wavelength ranges.

Optical system 20 comprises, from bottom to top in FIG. 1:
an angular filter 22; and
a coating 24 covering angular filter 22 and comprising an upper surface 26.

Image acquisition system 5 further comprises means, not shown, for processing the signals output by image sensor 10, for example comprising a microprocessor.

Angular filter 22, covering image sensor 10, is capable of filtering the incident radiation according to the incidence of the radiation relative to upper surface 26, particularly so that each photodetector 14 only receives rays having an incidence relative to an axis perpendicular to upper surface 26 smaller than a maximum angle of incidence smaller than 45°, preferably smaller than 30°, more preferably smaller than 20°, more preferably still smaller than 10°. Angular filter 22 is capable of blocking the rays of the incident radiation having an incidence relative to an axis perpendicular to upper surface 26 greater than the maximum angle of incidence.

n the present embodiment, angular filter 22 comprises two opaque layers 30, 40 separated by an intermediate layer 35. Opaque layer 30 is crossed by holes 32 and opaque layer 40 is crossed by holes 42. The cross-section plane of FIG. 2 is located at the level of the opaque layer 40 of angular filter 22. Each layer 30, 40 is opaque to the radiation detected by photodetectors 14, for example, absorbing and/or reflective with respect to the radiation detected by photodetectors 14. According to an embodiment, each layer 30, 40 is absorbing in the visible range and/or near infrared, and/or infrared. Hereafter, the thickness of layer 30 is called “h1”, the thickness of layer 40 is called “h2”, and the thickness of intermediate layer 35 is called “H”. The thicknesses “h1” and “h2” of opaque layers 30, 40 may be identical or different.

According to an embodiment, the number of holes 32 is equal to the number of holes 42. Each hole 32 has one of holes 42 associated therewith. According to an embodiment, each hole 32 is aligned with one of holes 42 along a given direction, preferably perpendicular to surface 26. In FIG. 2, holes 42 are shown with a circular cross-section. Generally, the cross-section of holes 32, 42 in the top view may be circular, oval, or polygonal, for example, triangular, square, or rectangular. According to an embodiment, each hole 32 has the same cross-section as the hole 42 with which it is aligned. Further, in FIG. 1, holes 32, 42 are shown with a constant cross-section across the entire thickness of opaque layer 30, 40. However, the cross-section of each hole 32, 42 may vary across the thickness of opaque layer 30, 40.

According to an embodiment, holes 32 are arranged in rows and in columns and holes 42 are arranged in rows and in columns. Holes 32 may have substantially the same dimensions and holes 42 may have substantially the same dimensions. Call “w” the width of a hole 32 or 42 measured along the row or column direction. Width w corresponds to the diameter of hole 32, 42 in the case of a hole having a circular cross-section. According to an embodiment, holes 32 and 42 are regularly arranged along the rows and along the columns. Call “p” the pitch of holes 32 or 42, that is, the distance in top view between the centers of two successive holes 32 or 42 of a row or of a column. Holes 32 or 42 may all have the same width w. As a variant, holes 32 and 42 may have different widths w. According to an embodiment, the width w of holes 32 is substantially equal to the width of holes 42. According to an embodiment, the pitch p of holes 32 is substantially equal to the pitch p of holes 42.

Layer 30 comprising holes 32 forms a first elementary angular filter F1 and layer 40 comprising holes 42 forms a second elementary angular filter F2. The aspect ratio of the holes 32 of the first elementary angular filter F1 is equal to h1/w and the aspect ratio of the holes 42 of the second elementary angular filter F2 is equal to h2/w. The structure obtained by the stacking of the first and second elementary angular filters F1 and F2, with intermediate layer 35 interposed therebetween, is equivalent to a general angular filter 22 having an aspect ratio of its holes equal to (h1+h2 +H)/w. Angular filter 22 thus only gives way to the rays of the incident radiation having an incidence relative to upper surface 26 smaller than a maximum incidence angle a, which is defined by the following relation (1):

tan α=w(h1+h2+H) (1)

According to an embodiment, photodetectors 14 may be distributed in rows and in columns. According to an embodiment, the pitch p of holes 42 is smaller than the pitch of the photodetectors 14 of image sensor 10. In this case, a plurality of holes 42 may be located opposite a same photodetector 14. According to an embodiment, the pitch p of holes 42 is identical to the pitch of the photodetectors 14 of image sensor 10. Angular filter 22 is then preferably aligned with image sensor 10 so that each hole 42 is opposite a photodetector 14. According to an embodiment, the pitch p of holes 42 is larger than the pitch of the photodetectors 14 of image sensor 10. In this case, a plurality of photodetectors 14 may be located opposite a same hole 42.

Ratio (h1+h2+H)/w may vary from 1 to 10 or even be greater than 10. Pitch p may vary from 1 μm to 100 μm, for example, equal to approximately 15 μm. Height h1+H+h2 may vary from 1 μm to 1 mm, preferably from 10 μm to 100 μm. Each height h1 or h2 may vary from 1 μm to 50 μm. Each height H may vary from 1 μm to 100 μm. Width w may vary from 1 μm to 100 μm, for example, equal to approximately 10 μm.

According to an embodiment, each opaque layer 30, 40 is entirely made of a material at least absorbing for the wavelengths to be angularly filtered. According to an embodiment, at least one of opaque layers 30 and 40 is made of positive resist, that is, resist for which the portion of the resist layer exposed to a radiation becomes soluble to a developer and where the portion of the resist layer which is not exposed to the radiation remains non-soluble in the developer. At least one of opaque layers 30 and 40 may be made of colored resin, for example, a colored or black DNQ-Novolack resin or a DUV (Deep Ultraviolet) resist. DNQ-Novolack resins are based on a mixture of diazonaphtoquinone (DNQ) and of a novolack resin (phenolformaldehyde resin). DUV resists may comprise polymers based on polyhydroxystyrenes. Further, according to an example, each opaque layer 30 and 40 may be made of black resin absorbing in the visible range or a portion of the visible range and near infrared. According to another example, each opaque layer 30, 40 may further be a colored resin absorbing visible light of a given color, for example, blue light, in the case where image sensor 10 is only sensitive to light of a given color or in the case where image sensor 10 is sensitive to visible light and a filter of the given color is interposed between angular filter 22 and the object to be detected.

Holes 32 or 42 may be filled with air or filled with a material at least partially transparent to the radiation detected by photodetectors 14, for example polydimethylsiloxane (PDMS). As a variant, holes 32 or 42 may be filled with a partially absorbing material in order to chromatically filter the rays angularly filtered by angular filter 22. Angular filter 22 may then further play the role of a colored filter. This enables to decrease the thickness of system 5 with respect to the case where a colored filter distinct from angular filter would be present. The partially absorbing filling material may be a colored resin or a colored plastic material such as PDMS.

The filling material of holes 32 may be selected to have a refraction index matching with the coating 24 in contact with angular filter 22 or to rigidify the structure and improve the mechanical resistance of angular filter 22.

According to another embodiment, for the first elementary angular filter F1, layer 30 comprises a core made of a first material at least partly transparent to the radiation detected by photodetectors 14 and covered with a coating opaque to the radiation detected by photodetectors 14, for example, absorbing and/or reflective with respect to the radiation detected by photodetectors 14. The first material may be a resin. The second material may be a metal, for example, aluminum (Al) or chromium (Cr), a metal alloy, or an organic material.

Intermediate layer 35 is at least partially transparent to the radiation captured by photodetectors 14. Intermediate layer 35 may be made of a transparent polymer, particularly, of poly(ethylene terephthalate) PET, poly(methyl methacrylate) PMMA, cyclo olefin polymer (COP). Layer 35 may also be made of a colored material to filter a portion of the visible and/or infrared spectrum.

Coating 24 is at least partially transparent to the radiation captured by photodetectors 14. Coating 24 may be a resin, a hard coating intended to rigidify the surface, or an optically clear adhesive (OCA) enabling to assemble filter 20 with upper layer. Coating 24 may have a thickness in the range from 0.1 μm to 10 mm. Upper surface 26 may be substantially planar.

According to an embodiment, system 5 may further comprise an array of microlenses covering angular filter 22, for example, interposed between angular filter 22 and coating 24.

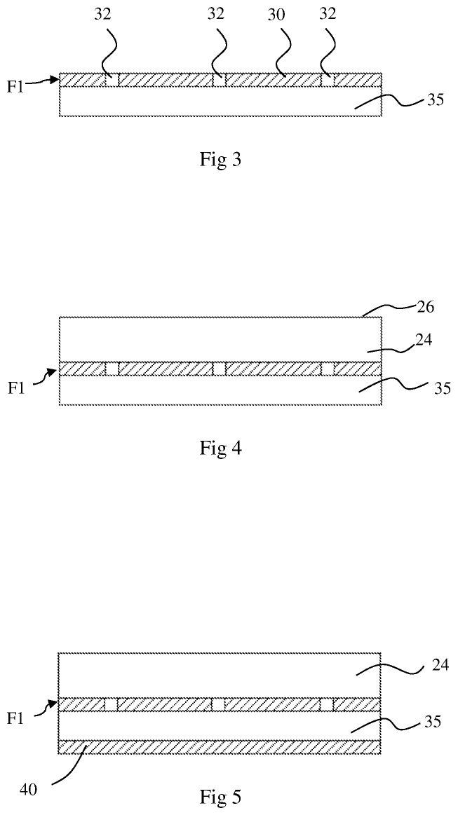

FIGS. 3 to 7 are partial simplified cross-section views of structures obtained at successive steps of an embodiment of a method of manufacturing the optical system 20 shown in FIGS. 1 and 2.

FIG. 3 shows the structure obtained after the forming of first elementary angular filter F1 on intermediate layer 35. As a variant, first elementary angular filter F1 may be formed on a support different from intermediate layer 35 and then be transferred onto intermediate layer 35.

An embodiment of a method of manufacturing first elementary angular filter F1, when layer 30 is entirely made of an opaque material, comprises the steps of:
depositing an opaque resin layer 30 on intermediate layer 35 of thickness h1;
printing the patterns of holes 42 in resin layer 30 by photolithography; and
developing the resin layer to form holes 42.

Another embodiment of a method of manufacturing first elementary angular filter F1, when layer 30 is entirely made of an opaque material, comprises the steps of:
forming a mold, by photolithography steps, having a shape complementary to the desired shape of holes 32;
filling the mold with the material forming hole 30; and
removing the obtained structure from the mold.

Another embodiment of a method of manufacturing first elementary angular filter F1, when layer 30 is entirely made of an opaque material, comprises perforating an opaque film of thickness h1, for example, a PDMS, PMMA, PEC, COP film. The perforation may be performed by using a micro-perforation tool for example comprising micro-needles to obtain the dimensions of holes 32 and the pitch of the desired holes 32.

When first elementary angular filter F1 comprises a core made of a first material at least partly transparent to the radiation detected by photodetectors 14 and covered with a coating opaque to the radiation detected by photodetectors 14, an embodiment of a method of manufacturing first angular filter F1 comprises the steps of:
depositing a transparent resin layer on intermediate layer 35 forming the core of layer 30, for example, by spin coating or by slot die coating;
printing the patterns of holes 32 in the resin core by photolithography;
developing the resin core to form holes 32; and
forming a coating on the transparent resin core, particularly by a selective deposition, for example, by evaporation, of the second material only on the transparent resin core and particularly on the lateral walls of holes 32, or by deposition of a layer of the second material on the transparent resin core and on intermediate layer 35 at the bottom of holes 32 and by removal of the second material present on intermediate layer 35.

FIG. 4 shows the structure obtained after the forming of coating 24 on the first elementary angular filter F1. According to an embodiment, the forming of coating 24 may comprise the lamination of a film on first elementary angular filter F1. In this case, holes 32 may be previously filled with a filling material. As a variant, coating 24 may be formed by depositing a liquid or viscous layer of the material forming coating 24 on the first elementary angular filter F1. The liquid layer thus fills holes 32. This layer is preferably self-planarizing, that is, it automatically forms a substantially planar free surface. The liquid layer is then cured to form coating 24. This may comprise a step of crosslinking of the material forming coating 24.

FIG. 5 shows the structure obtained after the forming of opaque layer 40 on intermediate layer 24, on the side opposite to first elementary angular filter F1. Opaque layer 40 may be deposited by liquid deposition, by cathode sputtering, or by evaporation. Methods such as spin coating, spray coating, heliography, slot-die coating, blade coating, flexography, or silk-screening, may in particular be used. According to the implemented deposition method, a step of drying of the deposited material may be provided.

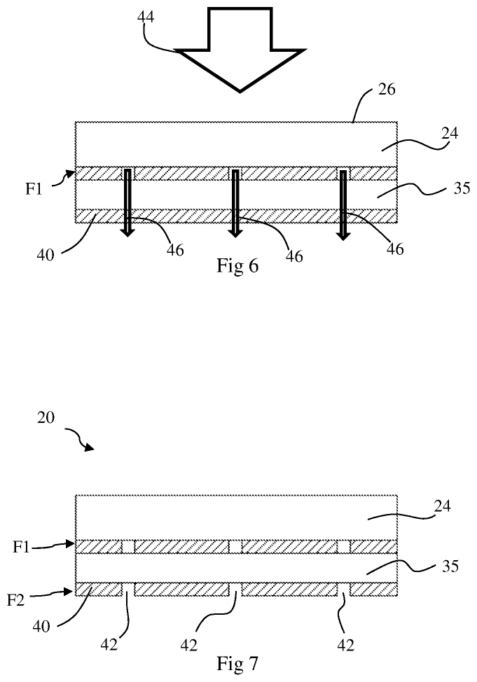

FIG. 6 shows the structure obtained during a step of exposure to a radiation 44, crossing first elementary angular filter F1, of portions 46 of opaque layer 40 at the desired locations of holes 42. The radiation used to expose opaque layer 40 depends on the resist used. As an example, radiation 44 is a radiation having wavelengths approximately in the range from 300 nm to 450 nm in the case of a DNQ-Novolack resin or an ultraviolet radiation for a DUV resist. The duration of the exposure of opaque layer 40 to radiation 44 particularly depends on the type of positive resist used and is sufficient for the exposed portions 46 of opaque layer 40 to extend across the entire thickness of opaque layer 40.

The exposure of opaque layer 40 is performed through first elementary angular filter F1. According to an embodiment, the incident radiation 44 which reaches the first elementary angular filter F1 is a substantially collimated radiation. Preferably, the inclination of radiation 44 relative to upper surface 26 substantially corresponds to the average inclination formed by the radiation 6 captured by photodetectors 14 with upper surface 26 during a normal use of image acquisition system 5. According to another embodiment, the conditions of exposure of surface 26 to radiation 44 substantially correspond to the conditions of illumination of surface 26 by radiation 6 in normal use, with an inclination of radiation 44 which may be non-uniform over the entire surface 26. In this case, the exposed portions 46 may vary in terms of dimensions with respect to one another and the relative position between each exposed portion 46 and the associated hole 32 may vary from one hole 32 to the other.

FIG. 7 shows the structure obtained during a step of development of opaque layer 40 which has caused the dissolution, in a developer, of the portions 46 of opaque layer 40 exposed to incident radiation 44, thus forming holes 42. The second elementary angular filter F2 is thus obtained. The composition of the developer depends on the nature of the positive resist which has been used.

The method may comprise subsequent steps comprising the filling of holes 42 with a filling material and the bonding of the optical system 20 thus obtained to image sensor 10.

Advantageously, the alignment of holes 32 with respect to microlenses 42 is obtained automatically by the very method of forming holes 42.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional indications provided hereinabove.

1. A method of manufacturing an optical system comprising an angular filter comprising a stack of first and second elementary angular filters, the method comprising exposing a layer of positive resist through the first elementary angular filter and removing the exposed portions of the layer to form holes crossing said layer, said layer crossed by said holes forming the second elementary angular filter.

2. The method according to claim 1, wherein the optical system comprises a surface intended to receive a first radiation, the layer being opaque to the first radiation, the angular filter being configured to block the rays of said first radiation having an incidence relative to a direction orthogonal to the surface greater than a threshold and to give way to rays of said first radiation having an incidence relative to a direction orthogonal to the surface smaller than the threshold.

3. The method according to claim 2, wherein the exposure step comprising exposing the layer to a second radiation through the first elementary angular filter, the positive resist being photosensitive to the second radiation.

4. The method according to claim 2, wherein the first radiation is in the visible range and/or in the infrared range.

5. The method according to claim 1, wherein each first and second elementary angular filter comprises a layer crossed by holes.

6. An optical system comprising an angular filter comprising a stack of first and second elementary angular filters, the second elementary angular filter comprising a layer of positive resist and holes crossing said layer.

7. The optical system according to claim 6, further comprising a surface intended to receive a first radiation, the layer being opaque to the first radiation, the angular filter being configured to block the rays of said first radiation having an incidence relative to a direction orthogonal to the surface greater than a threshold and to give way to rays of said first radiation having an incidence relative to a direction orthogonal to the surface smaller than the threshold.

8. The optical system according to claim 7, wherein the positive resist is photosensitive to the second radiation.

9. The optical system according to claim 7, further comprising an additional layer interposed between the first elementary angular filter and the second elementary angular filter at least partially transparent to the first radiation.

10. The optical system according to claim 9, wherein, for each hole, the ratio of the sum of the thicknesses of the first elementary angular filter, of the additional layer, and of the second elementary angular filter, measured perpendicularly to the surface, to the width of the hole, measured parallel to the surface, is greater than 1.

11. The optical system according to claim 7, wherein the holes are arranged in rows and in columns, the pitch between adjacent holes of a same row or of a same column varying from 1 μm to 100 μm.

12. The optical system according to claim 7, wherein the height of each hole, measured along a direction orthogonal to the surface, varies from 1 μm to 50 μm.

13. The optical system according to claim 7, wherein the width of each hole measured parallel to the surface varies from 1 μm to 100 μm.
